(19) United States
(12) Patent Application Publication
(10) Pub. No.: US 2005/0104164 A1
(43) Pub. Date: May 19, 2005

(54) EMI shielded integrated circuit packaging apparatus method and system

(75) Inventors: Abiola Awujoola, Union City, CA (US); Clifford R. Fishley, San Jose, CA (US)

Correspondence Address: LSI LOGIC CORPORATION, 1621 BARBER LANE, MS: D-106, MILPITAS, CA, 95035, US

(73) Assignee: LSI LOGIC CORPORATION, Milpitas, CA (US)

(21) Appl. No.: 10/713,952

(22) Filed: Nov. 14, 2003

(51) Int. Cl. H01L 23/552

(52) U.S. Cl. 257/659

(57) ABSTRACT

A package shell that is electrically and thermally conductive is placed over an integrated circuit die and associated wire-bond connections to electromagnetically shield the resulting integrated circuit package. The package shell is attached to the top surface of a substrate bearing the integrated circuit die and is electrically connected to a grounding path. The package shell may be filled with a thermally conductive filler in order to increase the heat dissipation and EMI shielding of the resulting integrated circuit package.

### BACKGROUND OF THE INVENTION

1. Field of the Invention

The present invention relates generally to electronic circuits and systems. Specifically, the invention relates to apparatus, methods, and systems for packaging integrated circuits.

2. Description of the Related Art

Semiconductor circuit technologies have experienced a steady march of process and materials improvements since their introduction in the later half of the 20^{th} century. Such improvements have significantly decreased the geometry sizes of semiconductor devices while dramatically increasing the density, clock rates, and processing power attainable on a single chip. Despite the tremendous increase in device density achievable with semiconductors, integrated circuit packaging has limited the ability to achieve a corresponding increase in density on board level products. In addition, the aforementioned improvements have also increased the spectral emissions, I/O requirements, and heat generating capacity per unit area of semiconductor material resulting in additional challenges for packaging technologies.

To address the needs resulting from improvements in semiconductor technology, a number of changes in packaging technology have been undertaken to varying degrees of success. For example, pin grid arrays, flat packs, multi-chip modules, ball grid arrays, and flip chips have all experienced some degree of commercial success. However, many of these improvements in packaging technology have proven to be too expensive to be useful for commodity parts and circuits.

One notable exception is ball grid array (BGA) packaging technology. Since solder ball connections can be cost effectively place underneath a package in a dense two dimensional array rather than just around the package perimeter, ball grids arrays have resulted in smaller packages with high I/O capacity.

Several problems are aggravated with the increase chip density attainable with BGA and other high density packaging techniques. One is heat dissipation. Smaller packages have a reduced surface area in which to dissipate the heat generated by an integrated circuit. Another problem resulting from increase chip density is electromagnetic interference (EMI). Since electromagnetic radiation is generally reduced by a factor of 1/D², where D is the distance to an electromagnetic source, shorter distances between packages significantly increases the electromagnetic interference experienced by adjacent chips.

What is needed is a packaging solution that addresses the challenges of smaller integrated circuit packages. Specifically, what is needed is a packaging solution that increases the heat dissipation and EMI protection of high density integrated circuit packages such as BGA packages.

### BRIEF SUMMARY OF THE INVENTION

The present invention has been developed in response to the present state of the art, and in particular, in response to the problems and needs in the art that have not yet been fully solved by currently available integrated circuit packaging means and methods. Accordingly, the present invention has been developed to provide an apparatus, method, and system for packaging an integrated circuit that overcome many or all of the above-discussed shortcomings in the art.

In one aspect of the present invention, an apparatus for packaging an integrated circuit includes a substrate with a grounding path, an integrated circuit die attached to the top surface of the substrate, a plurality of die connections that electrically connect the integrated circuit die to the substrate, and a package shell attached to the top surface of the substrate and electrically connected to the grounding path.

The package shell is constructed of an electrically conductive material that electromagnetically shields the integrated circuit die and associated die connections. The shape of the package shell facilitates covering a substantial portion of the substrate while providing horizontal and vertical clearance for the integrated circuit die and associated die connections. In one embodiment, the package shell is formed and shaped by stamping a metallic sheet such as copper.

The package shell may be made of a thermally conductive material and configured to function as a heat spreader. In certain embodiments, the package shell is filled with a thermally conductive filler that thermally couples the integrated circuit die to the package shell and thereby increases the thermal conductivity of the integrated circuit package. The package shell covers, protects, electromagnetically shields, and dissipates heat from the integrated circuit die and the plurality of die connections.

In one embodiment, the package shell is attached to the substrate and electrically connected to the grounding path with an electrically conductive adhesive such as a silver-filled epoxy. In certain embodiments, the package shell features one or more ports or vents that may be used to fill the package shell with a thermally conductive filler while venting gases displaced by the thermally conductive filler.

The present invention may also include a package frame that laterally surrounds the package shell and seals the package shell to the substrate. In certain embodiments, the thermally conductive filler and the package frame are the same material and may be concurrently formed by a mold injection process.

In certain embodiments, the substrate is essentially a printed circuit board with an array of solder balls attached to connecting pads on the bottom of the substrate. The array of solder balls provides a high density electrical interface and facilitates connecting the integrated circuit package to a circuit board that interconnects multiple integrated circuit packages.

In another aspect of the invention, a method for packaging an integrated circuit includes attaching an integrated circuit die to a top surface of a substrate, connecting the integrated circuit die to the substrate with a plurality of die connections, attaching a package shell to the top surface of the substrate, and electrically connecting the package shell to a grounding path. In certain embodiments, electrically connecting the package shell to a grounding path is accomplished by bonding the package shell to the substrate with an electrically conductive adhesive such as a silver-filled epoxy. The package shell covers and electromagnetically shields the integrated circuit die and the plurality of die connections. The package shell may also dissipate heat from the integrated circuit die and physically protect the integrated circuit die.

The method for packaging an integrated circuit may also include filling the package shell with a thermally conductive filler that thermally couples the integrated circuit die to the package shell and also laterally surrounding the package shell with a package frame. In certain embodiments, filling the package shell with a thermally conductive filler and laterally surrounding the package shell with a package frame is concurrently accomplished by molding the package frame around the perimeter of the package shell. The method may also include attaching an array of solder balls to the connecting pads.

In another aspect of the present invention, a system for packaging an integrated circuit includes a circuit board that interconnects multiple integrated circuit packages, a power supply configured to power the circuit board, and one or more integrated circuit packages of the present invention. The system for packaging an integrated circuit facilitates attaining reliable high-density electronic systems in a cost-effective manner.

The various elements and aspects of the present invention improve the EMI shielding characteristics of an integrated circuit package while also increasing the thermal conductivity of the integrated circuit package. These and other features and advantages of the present invention will become more fully apparent from the following description and appended claims, or may be learned by the practice of the invention as set forth hereinafter.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 is a perspective view illustration depicting one embodiment of a partially assembled integrated circuit package of the present invention;

FIG. 2 is a perspective view illustration depicting one embodiment of a fully assembled integrated circuit package of the present invention;

FIG. 3 is a cross-sectional illustration depicting one embodiment of an integrated circuit package of the present invention;

FIG. 4 is a flow chart diagram depicting one embodiment of an integrated circuit packaging method of the present invention;

FIG. 5 is a side view illustration depicting one embodiment of a package shell of the present invention;

FIG. 6 is a top view illustration further depicting the package shell of FIG. 5;

FIG. 7 is a side view illustration depicting one embodiment of a package shell of the present invention;

FIG. 8 is a top view illustration further depicting the package shell of FIG. 7;

FIG. 9 is a side view illustration depicting one embodiment of a package shell of the present invention; and

FIG. 10 is a top view illustration further depicting the package shell of FIG. 9.

### DETAILED DESCRIPTION OF THE INVENTION

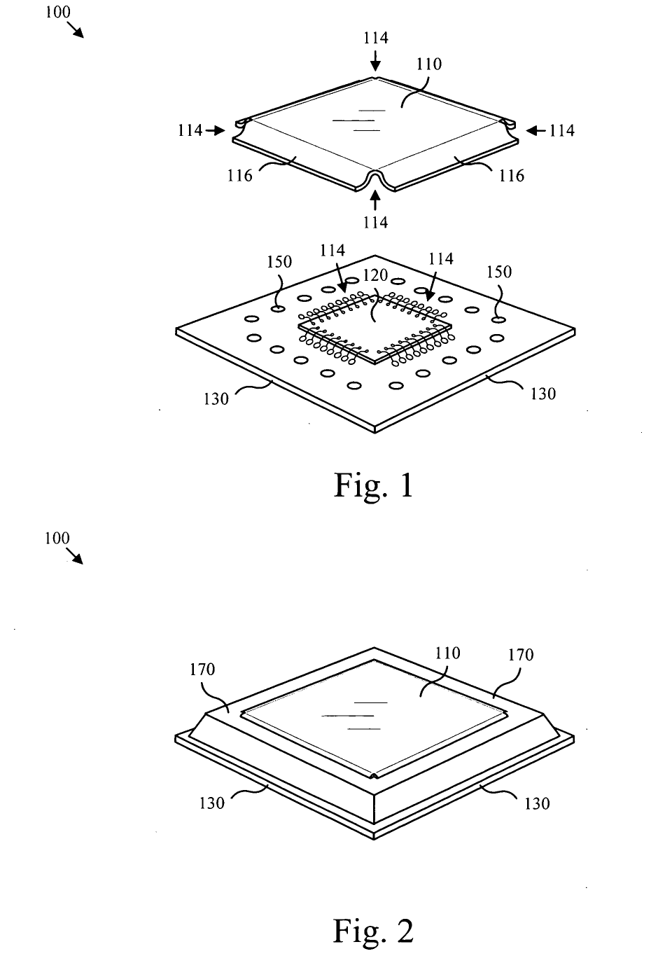

It will be readily understood that the components of the present invention, as generally described and illustrated in the Figures herein, may be arranged and designed in a wide variety of different configurations. Thus, the following more detailed description of the embodiments of the apparatus, method, and system of the present invention, as represented in FIGS. 1 through 10, is not intended to limit the scope of the invention, as claimed, but is merely representative of selected embodiments of the invention.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment and the described features, structures, or characteristics may be combined in any suitable manner in one or more embodiments.

FIGS. 1-3 depict certain embodiments of an integrated circuit package 100 of the present invention. As depicted, the integrated circuit package 100 includes a package shell 110, an integrated circuit die 120, a substrate 130, a set of die connections 140, one or more grounding pads 150, a thermally conductive filler 160, an optional package frame 170, and a connection array 180. The integrated circuit package 100 packages, protects, cools, and electromagnetically shields the integrated circuit die 120.

The package shell 110 is shaped to attach to the substrate 130 and cover the integrated circuit die 120 and the die connections 140. The package shell is constructed of an electrically conductive material that facilitates electromagnetically shielding the integrated circuit die 120 and the die connections 140. In each of the embodiments depicted in FIGS. 1-10, the package shell 110 provides sufficient horizontal and vertical clearance such that the integrated circuit die 120 and the die connections 140 may reside under the package shell 110 without contacting the package shell 110.

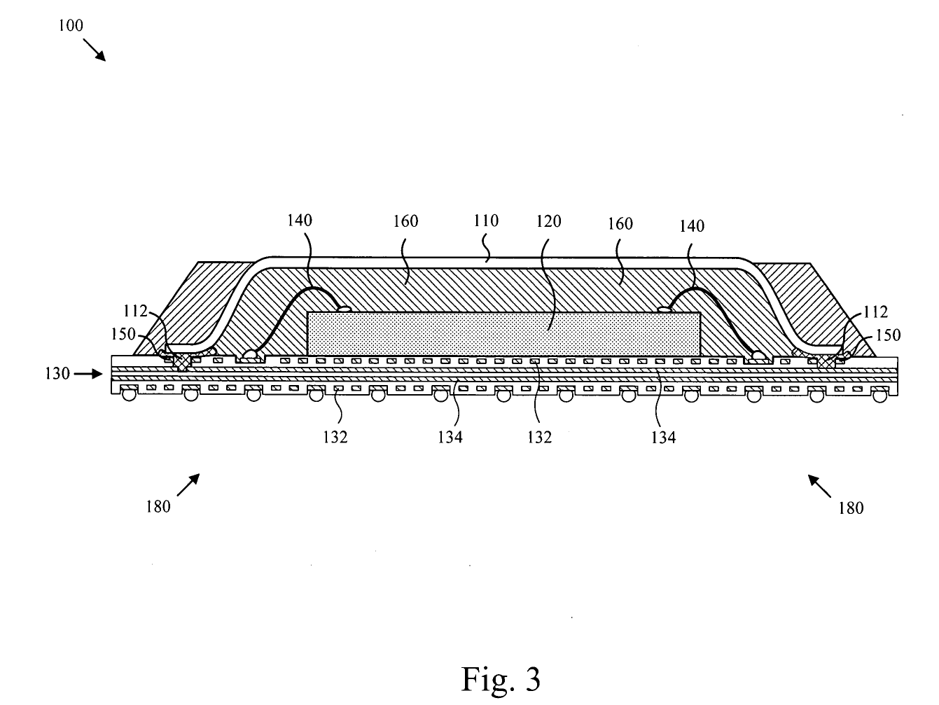

The substrate 130 depicted in FIGS. 1 and 3 includes the grounding pads 150, which are used to ground the package shell 110 and improve the shielding characteristics of the integrated circuit package 100. In the depicted embodiment, the package shell 110 is bonded to the substrate 130 and the grounding pads 150 with an electrically conductive adhesive 112 as shown in FIG. 3.

The package shell 110 may include one or more ports or vents 114. The ports or vents 114 facilitate filling the package shell 110 with the thermally conductive filler 160 during manufacture of the integrated circuit package 100. The thermally conductive filler 160 thermally connects the integrated circuit die 120 with the package shell 110 to facilitate cooling of the integrated circuit die 120. In certain embodiments, the package shell 110 is a heat spreader made of a material with high thermal conductivity such as copper.

The thermally conductive filler 160 may be a standard molding compound or a thermally enhanced molding compound. In one embodiment, the thermally conductive filler 160 is a standard molding compound made of quartz particles and an epoxy resin binder. In another embodiment, the thermally conductive filler 160 is a thermally enhanced molding compound made of Alumina (Al₂O₃) and/or Aluminum Nitrite (AlN) particles and an epoxy resin binder.

As shown in FIG. 3, the substrate 130 may be a multi-layer substrate containing one or more signal layers 132 and ground/power layers 134. In certain embodiments, the substrate 130 is essentially a printed circuit board. The die connections 140 electrically connect the integrated circuit die 120 to the substrate 130. For example, the die connections 140 may be wire-bond connections.

The package frame 170 provides additional stiffness to the integrated circuit package 100. In the depicted embodiment, the package frame 170 laterally surrounds the package shell 110 and covers a shell brim or edge 116 and a substantial portion of the substrate 130 and thereby seals the integrated circuit package 100. The package frame 170 and the thermally conductive filler 160 may be made of the same material and fabricated with a single process step such as a molding operation. The package frame 170 may be vertically shorter than the package shell 110 such that the top surface of the package shell 110 protrudes above the package frame 170.

The connection array 180 facilitates connecting the integrated circuit package 100 to a printed circuit board or the like. In the depicted embodiment, the connection array 180 is a ball grid array. The connection array 180 provides electrical connectivity to other devices and packages.

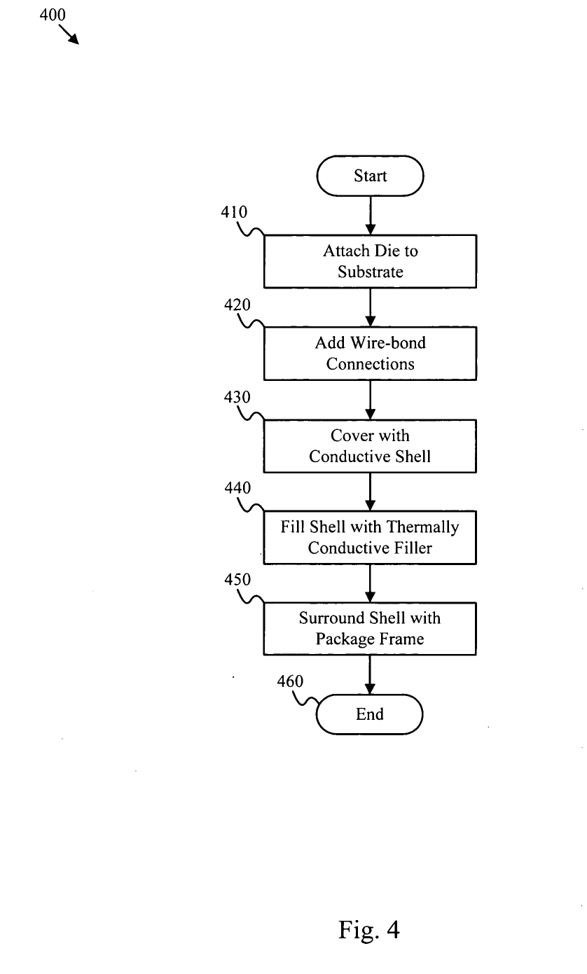

FIG. 4 is a flow chart diagram depicting one embodiment of an integrated circuit packaging method 400 of the present invention. As depicted, the integrated circuit packaging method 400 includes an attach die step 410, an add die connections step 420, a cover with conductive shell step 430, a connect shell step 440, a fill shell step 450, and a frame shell step 460. The integrated circuit packaging method 400 may be used to manufacture the integrated circuit package 100, or the like.

The attach die step 410 attaches an integrated circuit die to a substrate or the like. In one embodiment, the die is bonded to the substrate with an adhesive. The add die connections step 420 adds electrical connections between the substrate and the integrated circuit die. In one embodiment, the electrical connections are wire-bond connections made between bonding pads on the substrate and the integrated circuit die.

The cover with conductive shell step 430 covers the integrated circuit die and the associated electrical connections with a package shell that is electrically conductive, such as the package shell 110 depicted in FIGS. 1-3, and 5-10. The package shell may also be thermally conductive. In one embodiment, the package shell is formed and shaped by stamping a metallic sheet made of a conductive material such as copper.

The connect shell step 440 connects the package shell to a grounding path. Connecting the package shell to a grounding path improves the electromagnetic shielding provided by the integrated circuit packaging method 400. In one embodiment, the package shell is connected to a grounding path by aligning the package shell with grounding pads on the substrate and bonding the package shell to the substrate with an electrically conductive adhesive such as a silver-filled epoxy. In certain embodiments, the cover conductive shell step 430 and the connect shell step 440 are concurrently conducted as a single process step.

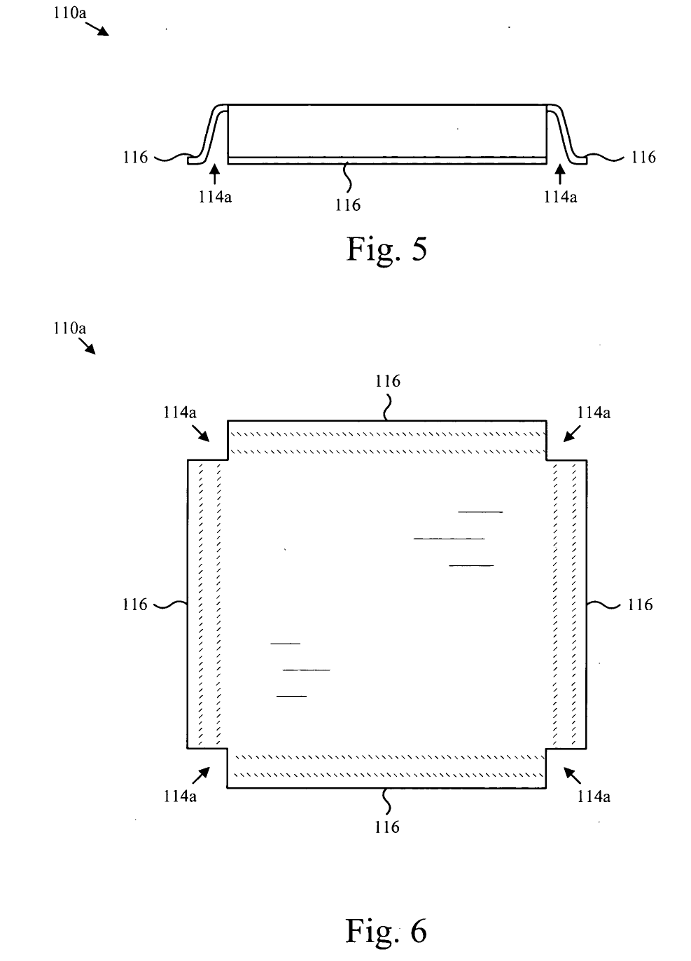

The fill shell step 450 fills the package shell with a thermally conductive filler such as a molding compound made of quartz particles and an epoxy resin binder Filling the package shell with a thermally conductive filler increases the thermal conductivity and cooling capacity of the manufactured package. The package shell may be filled by inserting an injection nozzle over, or into, one or more ports or vents such as the various ports and vents depicted in FIGS. 5-10.

In certain embodiments, the ports or vents used for filling the package shell are left open after filling. In other embodiments, the ports or vents are sealed after the shell is filled. For example, the package shell may include tabs that are bent into position to seal the ports or vents. Alternately, portions of the electrically conductive shell may be pinched together to seal the ports or vents. Sealing the ports or vents increases the range of electromagnetic frequencies that are attenuated by the package shell.

The frame shell step 460 frames the package shell with a package frame. In one embodiment, the shell is framed by molding a plastic resin over the edge or brim of the shell that also covers a region of the substrate immediately surrounding the package shell. The package frame may stiffen the integrated circuit package and seal the package shell to the substrate.

In one embodiment, the package shell substantially covers the entire substrate, and the frame shell step 460 is omitted from the integrated circuit packaging method 400. In another embodiment, the fill shell step 450 and the frame shell step 460 are concurrently conducted by an injection molding process.

FIGS. 5 and 6 are respective side and top view illustrations that depict one embodiment of a package shell 110a of the present invention. The package shell 110a is one example of a manner of configuration of the package shell 110 of the present invention. The package shell 110a includes an open region 114a at each corner that may be used as a port or vent 114 while filling the shell with a thermally conductive filler or the like. In one embodiment, the package shell 110a is stamped from a sheet of electrically conductive material.

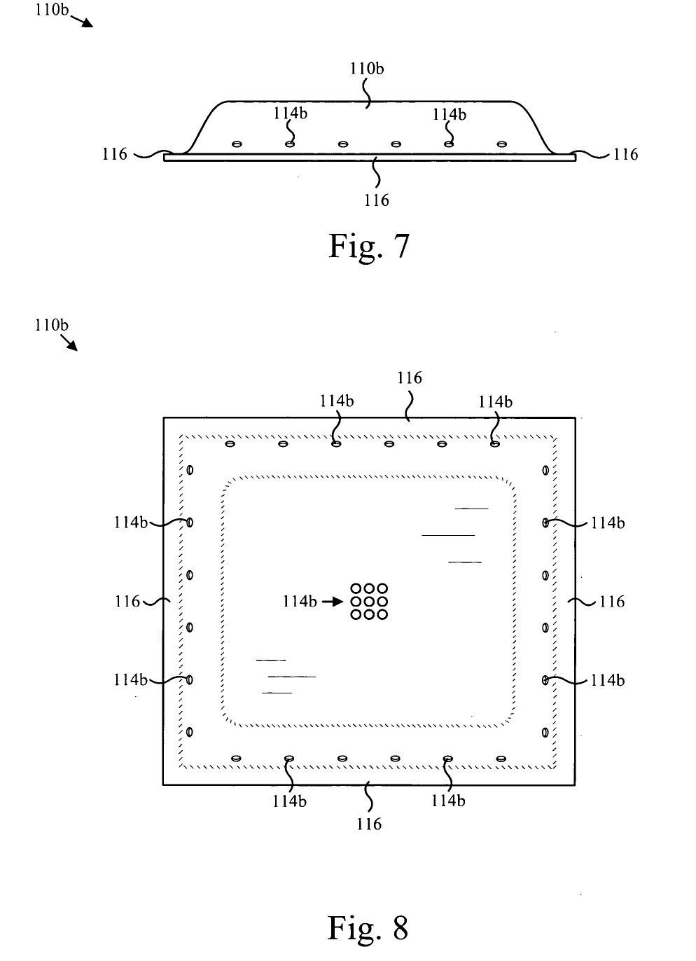

FIGS. 7 and 8 are respective side and top view illustrations that depict one embodiment of a package shell 110b of the present invention. The package shell 110b is an additional example of a manner of configuration of the package shell 110 of the present invention. The package shell 110b includes a series of small ports 114b that may be used to fill the shell with a thermally conductive filler, or the like. In one embodiment, the ports 114b positioned near the center of the package shell 110b are used to fill the shell with a thermally conductive filler while the ports 114b positioned around the perimeter of the package are be used to vent air displaced by the thermally conductive filler. The small size of the ports 114b increases the range of electromagnetic frequencies that are attenuated by the package shell 110b. In one embodiment, the package shell 110b is stamped from a sheet of electrically conductive material.

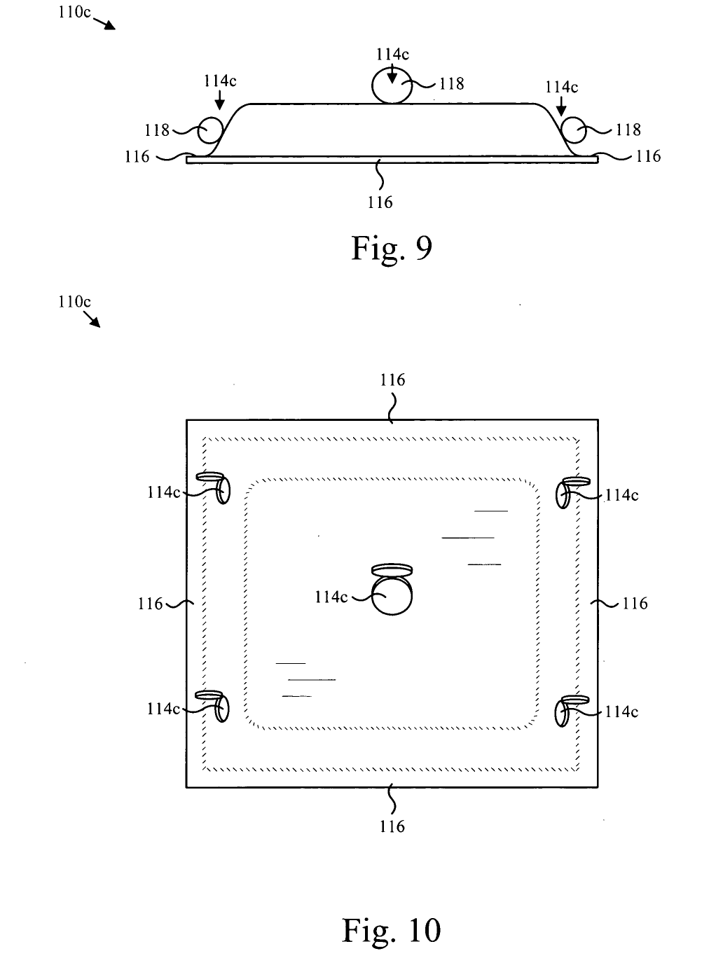

FIGS. 9 and 10 are respective side and top view illustrations that depict one embodiment of a package shell 110c of the present invention. The package shell 110c is yet another example of a manner of configuration of the package shell 110 of the present invention. In one embodiment, the package shell 110c is stamped from a sheet of electrically conductive material.

The package shell 110c includes a set of ports 114c that may be used to fill the shell with a thermally conductive filler and a set of tabs 118 that may be used to seal the ports 114c subsequent to the filling process. In the depicted arrangement, the port 114c positioned at the center of the package shell 110c may be used to inject the thermally conductive filler while the ports 114c positioned around the perimeter of the package shell 110c may be used to vent air displaced by the thermally conductive filler.

The present invention improves the EMI shielding characteristics of integrated circuit packages while also increasing the thermal conductivity of such packages. The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. An apparatus for packaging an integrated circuit, the apparatus comprising:
a substrate comprising a grounding path;
an integrated circuit die attached to the top surface of the substrate;
a plurality of die connections connecting the integrated circuit die to the substrate; and
a package shell attached to the top surface of the substrate and electrically connected to the grounding path, the package shell configured to cover and electromagnetically shield the integrated circuit die and the plurality of die connections.

2. The apparatus of claim 1, wherein the package shell is filled with a thermally conductive filler configured to thermally couple the integrated circuit die to the package shell.

3. The apparatus of claim 1, wherein the die connections are wire-bond connections.

4. The apparatus of claim 1, wherein the package shell is a thermally conductive heat spreader.

5. The apparatus of claim 1, wherein the package shell is bonded to the substrate with an electrically conductive adhesive.

6. The apparatus of claim 5, wherein the electrically conductive adhesive is a silver-filled epoxy.

7. The apparatus of claim 1, wherein the package shell comprises at least one port configured to facilitate filling the package shell with a thermally conductive filler.

8. The apparatus of claim 1, wherein the package shell comprises at least one vent configured to vent gases displaced by a thermally conductive filler.

9. The apparatus of claim 1, further comprising a package frame configured to laterally surround the package shell.

10. The apparatus of claim 9, wherein the package frame is molded over a brim of the package shell.

11. The apparatus of claim 1, wherein the substrate is configured to electrically connect a plurality of bonding pads on the top surface of the substrate with an array of connecting pads on a bottom surface of the substrate.

12. The apparatus of claim 11, further comprising an array of solder balls attached to the connecting pads.

13. The apparatus of claim 1, wherein the substrate is a printed circuit board.

14. A method for packaging an integrated circuit, the method comprising:
attaching an integrated circuit die to a top surface of a substrate;
connecting the integrated circuit die to the substrate with a plurality of die connections;
attaching a package shell to the top surface of the substrate, the package shell configured to cover and electromagnetically shield the integrated circuit die and the plurality of die connections; and
electrically connecting the package shell to a grounding path.

15. The method of claim 14, further comprising filling the package shell with a thermally conductive filler configured to thermally couple the integrated circuit die to the package shell.

16. The method of claim 15, wherein filling the package shell with a thermally conductive filler comprises molding a package frame around a perimeter of the package shell.

17. The method claim 14, wherein electrically connecting the package shell to a grounding path comprises bonding the package shell to the substrate with an electrically conductive adhesive.

18. The method of claim 17, wherein the electrically conductive adhesive is a silver-filled epoxy.

19. The method of claim 14, wherein the substrate is a printed circuit board.

20. The method of claim 14, further comprising attaching an array of solder balls to the connecting pads.

21. The method of claim 14, further comprising laterally surrounding the package shell with a package frame.

22. The method of claim 21, wherein laterally surrounding the package shell with a package frame comprises molding the package frame over a brim of the package shell.

23. A system for packaging an integrated circuit, the system comprising:
a circuit board interconnecting a plurality of integrated circuit packages;
a power supply configured to power the circuit board; and
at least one package of the plurality of an integrated circuit packages comprising:
a substrate comprising a grounding path,
an integrated circuit die attached to the top surface of the substrate,
a plurality of die connections connecting the integrated circuit die to the substrate, and
a package shell attached to the top surface of the substrate and electrically connected to the grounding path, the package shell configured to cover and electromagnetically shield the integrated circuit die and the plurality of die connections.
